(19) United States
(12) Patent Application Publication
(10) Pub. No.: US 2025/0132677 A1
(43) Pub. Date: Apr. 24, 2025

(54) APPARATUS OF CONFIGURABLE PMIC WITH ARRAY OF MICRO INTEGRATED VOLTAGE REGULATION CELLS AND SHARED PROGRAMMABLE REFERENCES

(71) Applicant: PowerLattice Technologies Inc., Camas, WA (US)

(72) Inventors: Peng Zou, Camas, WA (US); Gang Ren, Camas, WA (US); Sujith Dermal, Chandler, AZ (US)

(21) Appl. No.: 18/919,345

(22) Filed: Oct. 17, 2024

Related U.S. Application Data
(60) Provisional application No. 63/592,109, filed on Oct. 20, 2023.

(51) Int. Cl. H02M 3/158; G06F 1/26; H01L 25/16; H02M 3/00

(52) U.S. Cl. CPC H02M 3/158; G06F 1/26; H01L 25/16; H02M 3/003; H10D 1/20

(57) ABSTRACT

This application is directed to providing rail voltages for an electronic system. The electronic system includes an array of voltage regulator cells and a plurality of reference circuits. The array of voltage regulator cells is configured to provide a plurality of voltage regulator sets, and each voltage regulator set is configured to output a respective rail voltage to a respective power rail of a plurality of power rails. The plurality of reference circuits are coupled to the array of voltage regulator cells. Each reference circuit is shared by, and configured to provide a respective reference voltage to, one or more respective voltage regulator cells of a respective voltage regulator set. The respective voltage regulator set is configured to generate the respective rail voltage based on the respective reference voltage.

### RELATED APPLICATION

This application claims benefit of U.S. Provisional Patent Application No. 63/592,109, titled “Apparatus of Configurable PMIC with Array of Micro Integrated Voltage Regulation Cells and Shared Programmable References,” filed Oct. 20, 2024, which is incorporated by reference in its entirety.

### TECHNICAL FIELD

This application relates generally to power management of an electronic system, including, but not limited to, methods, systems, devices, and integrated circuits for providing rail voltages to drive power rails of the electronic system.

### BACKGROUND

A System on Chip (SoC) consolidates multiple components of a computer, such as a processor, memory, input/output interfaces, and various peripherals, on a substrate. SoCs are widely used in modern electronics, including smartphones, tablets, and embedded systems, where space, power efficiency, and performance are critical. To manage complex power requirements of these components, a Power Management Integrated Circuit (PMIC) is employed. The PMIC is responsible for regulating, distributing, and controlling the power delivered to the SoC's various subsystems. It efficiently manages multiple voltage levels, enabling features like dynamic voltage scaling to conserve energy and ensure the SoC operates within its optimal power and thermal limits. Together, the SoC and PMIC form a highly efficient system capable of handling diverse tasks with minimal power consumption, making them essential in today's compact, high-performance devices. However, the PMIC applied with the SoC may face some issues with consistency among different power rails and stability within a single power rail. Consistency issues arise when different power rails fail to deliver uniform voltage levels or fail to sequence properly, leading to performance variations or even malfunctions in the SoC. This can be caused by mismatched regulation circuitry, differing load demands, or poor coordination between multiple power rails. Stability issues, on the other hand, affect individual power rails where voltage fluctuations, oscillations, or noise occur within a single rail. These problems can cause intermittent failures, timing errors, or degraded performance in the SoC.

### SUMMARY

In accordance with at least some implementations disclosed herein is the realization that an SoC requires consistent and reliable power delivery on its power rails. Each power rail delivers its rail voltage consistently, and different power rails providing the same rail voltage may need to be consistent with one another. Various implementations of this application are directed to methods, systems, devices, and integrated circuits for generating one or more rail voltages to power a plurality of power rails using a configurable power management integrated circuit (PMIC) that applies one or more consolidated reference circuits. The configurable PMIC includes an array of micro-integrated voltage regulator cells. A subset of voltage regulator cells may be selected and grouped to function as a power supply driving a power rail. The selected voltage regulator cells are driven by the same reference circuit In some implementations, the voltage regulator cells of the PMIC are grouped to form a plurality of power supplies, e.g., each of which outputs a programmable rail voltage, and a subset of voltage regulator cells corresponding to each respective power supply is driven by a respective common reference circuit.

In one aspect, an electronic system includes an array of voltage regulator cells and a plurality of reference circuits coupled to the array of voltage regulator cells. The array of voltage regulator cells is configured to provide a plurality of voltage regulator sets. Each voltage regulator set is configured to output a respective rail voltage, and provide the respective rail voltage to a respective power rail of a plurality of power rails. Each of the plurality of reference circuits is shared by, and configured to provide a respective reference voltage to, one or more respective voltage regulator cells of a respective voltage regulator set, and the respective voltage regulator set is configured to generate the respective rail voltage based on the respective reference voltage.

In another aspect, an apparatus includes a plurality of power rails configured to providing one or more rail voltages, an array of voltage regulator cells coupled to the plurality of power rails, and a plurality of reference circuits coupled to the array of voltage regulator cells. The array of voltage regulator cells is configured to provide a plurality of voltage regulator sets, and each voltage regulator set is configured to output a respective rail voltage to a respective power rail. Each of the plurality of reference circuits is shared by, and configured to provide a respective reference voltage to, one or more respective voltage regulator cells of a respective voltage regulator set, and the respective voltage regulator set is configured to generate the respective rail voltage based on the respective reference voltage.

In yet another aspect, a method is implemented to provide rail voltages for an electronic system (e.g., driving processors or memory modules). The method includes grouping voltage regulator cells in an array of voltage regulator cells to provide a plurality of voltage regulator sets. The method further includes, for each of the plurality of voltage regulator sets, generating a respective reference voltage by a respective one of a plurality of reference circuits, where the respective one of the plurality of reference circuits is shared by one or more respective voltage regulators of the respective voltage regulator set. The method further includes, for each voltage regulator set, generating a respective rail voltage by the respective voltage regulator set based on the respective reference voltage and providing the respective rail voltage to drive a respective one of a plurality of power rails.

These illustrative implementations and implementations are mentioned not to limit or define the disclosure, but to provide examples to aid understanding thereof. Additional implementations are discussed in the Detailed Description, and further description is provided there.

### BRIEF DESCRIPTION OF THE DRAWINGS

For a better understanding of the various described implementations, reference should be made to the Detailed Description below, in conjunction with the following drawings in which like reference numerals refer to corresponding parts throughout the figures.

FIG. 1 is a block diagram of an example electronic system, in accordance with some implementations.

FIGS. 2A and 2B are a top perspective view and a bottom perspective view of an example electronic system including an SoC, in accordance with some implementations, respectively.

FIGS. 3A and 3B are a top perspective view and a bottom perspective view of another example electronic system, in accordance with some implementations, respectively.

FIG. 4A is a high-level block diagram of an example PMIC module, in accordance with some implementations, and FIG. 4B is a detailed block diagram of an example PMIC module, in accordance with some implementations.

FIG. 5 is a schematic diagram of an example voltage regulator cell, in accordance with some implementations.

FIG. 6 is a conceptual diagram illustrating example two voltage regulator cells (also shown in FIG. 4B) for providing a rail voltage V_{RAIL}, in accordance with some implementations.

FIG. 7A is a perspective view of an example PMIC chip including a plurality of inductors coupled in a plurality of voltage regulator cells, in accordance with some implementations.

FIGS. 7B and 7C are two cross sectional views of a portion of the PMIC chip shown in FIG. 7A including two inductors of two voltage regulator cells, in accordance with some implementations.

FIG. 8 is a flow diagram of an example method for providing rail voltages for an electronic system, in accordance with some implementations.

Like reference numerals refer to corresponding parts throughout the several views of the drawings.

### DETAILED DESCRIPTION

Reference will now be made in detail to specific implementations, examples of which are illustrated in the accompanying drawings. In the following detailed description, numerous non-limiting specific details are set forth in order to assist in understanding the subject matter presented herein. But it will be apparent to one of ordinary skill in the art that various alternatives may be used without departing from the scope of claims and the subject matter may be practiced without these specific details. For example, it will be apparent to one of ordinary skill in the art that the subject matter presented herein can be implemented on many types of electronic devices with storage capabilities.

In accordance with at least some implementations disclosed herein is the realization that an SoC requires consistent and reliable power delivery on its power rails. Each power rail delivers its rail voltage consistently, and different power rails providing the same rail voltage may need to be consistent with one another. Various implementations of this application are directed to methods, systems, devices, and integrated circuits for generating one or more rail voltages to power a plurality of power rails using a configurable power management integrated circuit (PMIC) that applies one or more consolidated reference circuits. The configurable PMIC includes an array of micro-integrated voltage regulator cells. A subset of voltage regulator cells may be selected and grouped to function as a power supply driving a power rail. The selected voltage regulator cells are driven by the same reference circuit In some implementations, the voltage regulator cells of the PMIC are grouped to form a plurality of power supplies, e.g., each of which outputs a programmable rail voltage, and a subset of voltage regulator cells corresponding to each respective power supply is driven by a respective common reference circuit.

In accordance with at least some implementations disclosed herein is the realization that a challenge of grouping a set of voltage regulator cells is load current balancing (or sharing) among the voltage regulator cells when each voltage regulator cell has a respective regulation control loop. Stated another way, two voltage regulator cells provide different output voltages and experience a load current imbalance, potentially causing a power rail coupled to these two voltage regulator cells to malfunction and permanently damage electronic components powered by the power rail.

To overcome this issue, a reference circuit is shared among a set of voltage regulator cells coupled to the same power rail. An output voltage of each voltage regulator cell tracks a respective reference voltage provided by the shared reference circuit. In some implementations, a digital-to-analog converter (DAC) provides a reference voltage that may drift based on different factors (e.g., locations, manufacturing conditions), even when the DAC is programmed using fixed digital input data. When the DAC is applied within a reference voltage source driving multiple voltage regulator cells coupled to the same power rail, the reference voltage drift jointly for the voltage regulator cells coupled to the same power rail, thereby making these voltage regulator cells perform consistently and stay in balance with one another. In some implementations, an array of DACs is coupled to a reference voltage distribution bus and a switch array, and configured to provide a common voltage reference to a set of voltage regulator cells that output the same rail voltage. Each voltage regulator cell does not have its self-contained DAC, thereby eliminating a current imbalance issue due to differences among self-contained DACs.

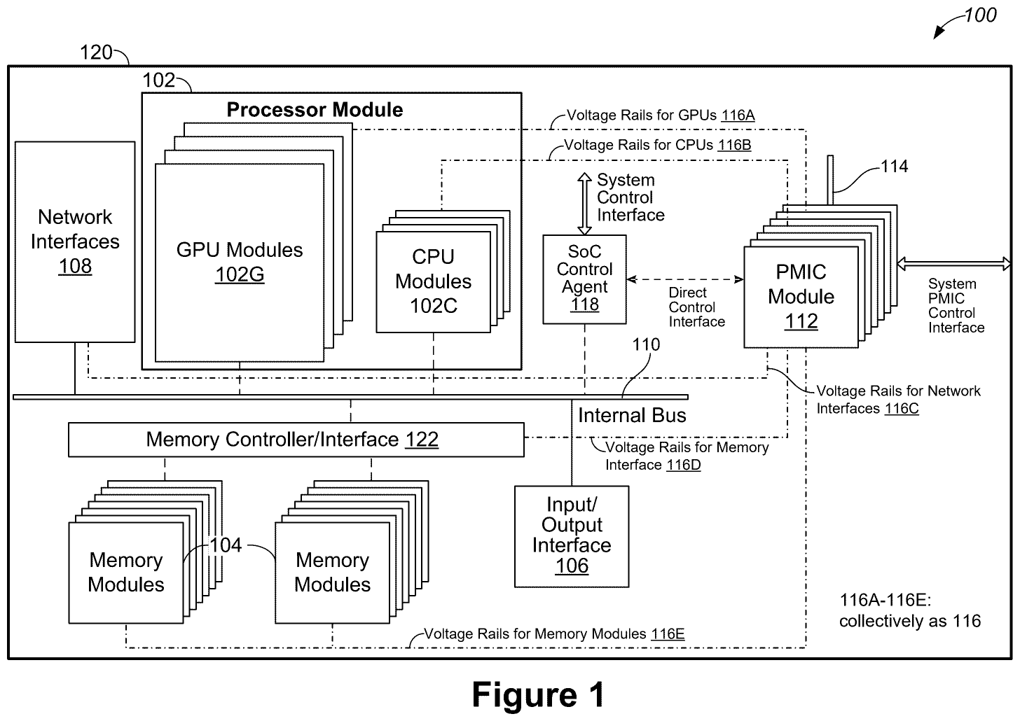

FIG. 1 is a block diagram of an example electronic system 100, in accordance with some implementations. The electronic system 100 includes at least a processor module 102, memory modules 104, an input/output (I/O) interface 106, one or more communication interfaces such as network interfaces 108, and one or more communication buses 110 for interconnecting these components. In some implementations, the I/O interface 106 allows the processor module 102 to communicate with an I/O device (e.g., a keyboard, a mouse or a trackpad). The I/O interface 106 may comply with a data communication bus standard including, but not limited to, universal serial bus (USB) and peripheral component interconnect express (PCIe). In some implementations, the communication bus(es) 110 include circuitry (sometimes called a chipset) that interconnects and controls communications among various system components included in electronic system 100. In some implementations, the electronic system 100 further includes other specialized hardware (e.g., wireless radios, graphics card, sound card, sensors).

In some implementations, the electronic system 100 further includes a PMIC module 112 configured to receive an input supply voltage 114. The PMIC module 112 is configured to modulate the received input supply voltage 114 to desired DC voltage levels, e.g., 5V, 3.3V or 1.8V, as required by various components or circuits (e.g., the processor module 102) within the electronic system 100. For example, the PMIC module 112 is configured to generate the DC voltage levels at a plurality of power rails 116 for providing power to other components (e.g. components 102-110) in the electronic system 100. Examples of the plurality of power rails 116 include, but are not limited to: one or more GPU power rails 116A, one or more CPU power rails 116B, one or more networking power rails 116C, one or more memory interface power rails 116D, and one or more memory module power rails 116E. In some implementations, the PMIC module 112 further includes a layer within a printed circuit board (PCB) or an integrated circuit (IC), and the layer is applied as an input power plane for distributing the input supply voltage 114.

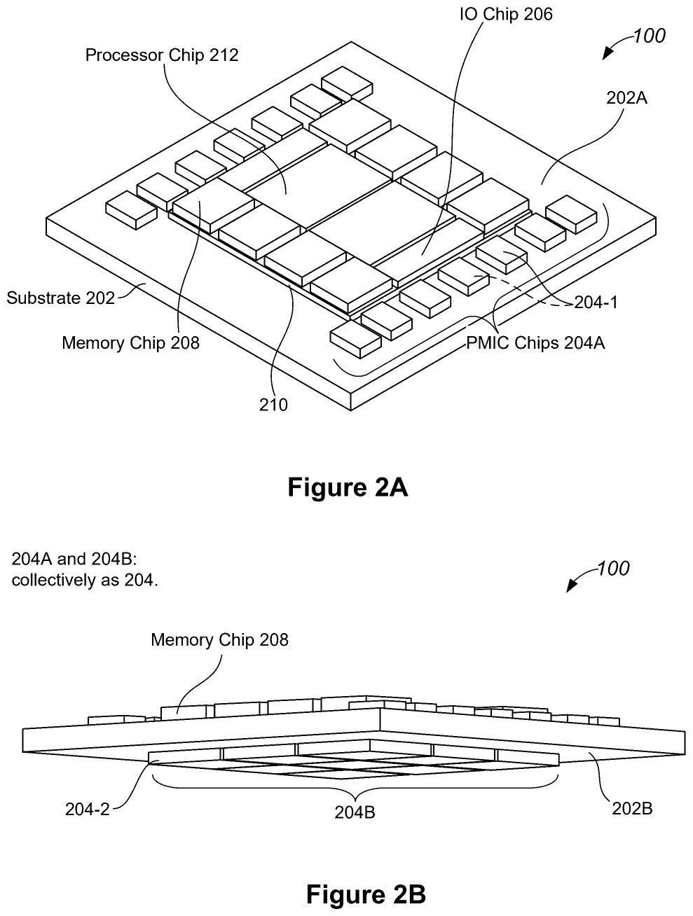

In some implementations, the electronic system 100 corresponds to an SoC 120. Different components of the electronic system 100 may be formed on two or more integrated circuits distributed on two or more chips, which are further assembled on a single substrate (e.g., substrate 202 in FIG. 2A) of the SoC 120. Alternatively, in some implementations, different components of the electronic system 100 are included in an integrated circuit formed on a single substrate of the SoC 120. In an example, the SoC 120 includes one of a silicon substrate, a polymeric substrate, a glass substrate, or a printed circuit board (PCB). Examples of the polymeric substrate include, but are not limited to, polyimide (PI), polyethylene terephthalate (PET), and polydimethylsiloxane (PDMS).

In some implementations, the SoC 120 further includes an SoC control agent 118 that refers to a control mechanism or module within the SoC 120. The SoC control agent 118 is configured to manage operation of different components (e.g., components 102-110) integrated on the SoC 120. More specifically, in some implementations, the SoC control agent 118 is configured to perform one or more of: resource management, inter-component communication, power management, task scheduling, security management, thermal management. For example, the SoC control agent 118 may allocate resources like power, processing time, and memory bandwidth to different components of the SoC 120; manages communication between various components, such as coordinating data transfers between the processor module 102 and peripherals; turn off or put certain components into a low-power state when they are not in use to conserve energy; manage scheduling of different tasks or operations across processing units of the processor module 102 within the SoC 120; implements security features (e.g., using hardware security modules, encryption, and access control); or monitor temperature sensors and adjusts operation (e.g., reducing clock speeds) to prevent overheating. In an example, the SoC control agent 118 includes one or more of: a power controller, a bus controller, and a clock controller. In some implementations, the SoC control agent 118 is implemented on a firmware level, e.g., adjusting system parameters dynamically based on workloads or external conditions.

In some implementations, the processor module 102 includes a plurality of processing units. In some implementations, the processor module 102 includes two or more different types of processing units including a subset of: one or more central processing units (CPUs) 102C, one or more graphics processing units (GPU) 102G, a digital signal processor (DSP), a neural processing unit (NPU) (also called artificial intelligence (AI) accelerator), an image signal processors (ISP), a video processing unit (VPU), an audio processing unit (APU), a secure microcontroller, and a field programmable gate array (FPGA). The CPUs 102C are configured to execute instructions from software (e.g., operating systems, applications). Examples of CPU architecture include, but are not limited to, reduced instruction set computing (RISC) and complex instruction set computing (CIS). The GPUs 102G are configured to render graphics and handle tasks that require parallel processing, such as image processing, video encoding/decoding, and machine learning.

In some implementations, the network interfaces 108 is configured to enable communication between the SoC 120 and external networks, such as local area networks (LANs) or the Internet, and includes both hardware and software components that handle data transmission, reception, and protocol management. The network interfaces 108 may include one or more interfaces for Wi-Fi, Ethernet, and Bluetooth networks, each allowing the electronic system 100 to exchange data with an external source, and participate in networked applications, such as IoT (Internet of Things), mobile communications, or cloud computing.

In some implementations, the memory modules 104 include high-speed random-access memory, such as static random-access memory (SRAM), double data rate (DDR) dynamic random-access memory (DRAM), or other random-access solid state memory devices. In some implementations, the memory modules 104 include non-volatile memory, such as one or more magnetic disk storage devices, optical disk storage devices, flash memory devices, or other non-volatile solid state storage devices. In some implementations, the memory modules 104, or alternatively the non-volatile memory device(s) within the memory modules 104, include a non-transitory computer readable storage medium. In an example, a memory module 104 includes a high bandwidth memory (HBM) configured to provide a data bandwidth greater than a bandwidth threshold to support GPUs 102G. The HBM includes a plurality of memory dies that are stacked vertically on top of each other. In some implementations, the electronic system 100 further includes a memory controller 122 coupled to manage memory access requests for the memory modules 104.

FIGS. 2A and 2B are a top perspective view and a bottom perspective view of an example electronic system 100, in accordance with some implementations, respectively. The electronic system 100 includes an SoC 120 having a substrate 202. The substrate 202 includes a first surface 202A and a second surface 202B that is opposite to the first surface 202A. The substrate 202 may be one of a silicon substrate, a polymeric substrate, a glass substrate, or a PCB. Examples of the polymeric substrate include, but are not limited to, PI, PET, and PDMS. In some implementations, each electronic component of the electronic system 100 corresponds to a region of the substrate 202, and includes a portion of an integrated circuit of the SoC 120. Alternatively, in some implementations, each electronic component of the electronic system 100 includes one or more chips that are mounted onto the substrate 202, e.g., with or without an intermediate support structure 210. In an example, the substrate 202 is made of a polymeric material, and the intermediate support structure 210 is made of silicon and applied to mechanically support a plurality of components (e.g., including an IO chip 206, a memory chip 208, a processor chip 212).

In some implementations not shown, all electronic components included in the electronic system 100 are disposed on the first surface 202A of the substrate 202. Alternatively, in some implementations, a first subset of electronic components of the electronic system 100 are disposed on the first substrate 202A of the substrate 202, and a second subset of electronic components of the electronic system 100 are disposed on the second substrate 202B of the substrate 202. In an example, one or more chips corresponding to a subset of the electronic components 102-108, 118, and 122 are disposed on the second surface 202B. In another example, one or more chips corresponding to the PMIC module 112 are disposed on the second surface 202B.

In some implementations, the PMIC module 112 includes a plurality of distinct PMIC chips 204, which further include a first set of PMIC chips 204A and a second set of PMIC chips 204B. The first set of PMIC chips 204A are disposed on the first surface 202A of the substrate 202, e.g., jointly with all or a subset of remainder components of the SoC 120 distinct form the PMIC module 112. The second set of PMIC chips 204B are disposed on the second surface 202B of the substrate 202. A rail voltage outputted by the first set of PMIC chips 204A is routed on or under the first surface 202A, e.g., by way of a configurable power plane, to access a power rail 116 of the remainder components of the SoC 120. In some implementations, a rail voltage is outputted by the second set of PMIC chips 204B and routed vertically across the substrate 202, from the second surface 202B to the first surface 202A, to access an associated power rail 116 located on or under the first surface 202A, e.g., by way of a configurable power plane.

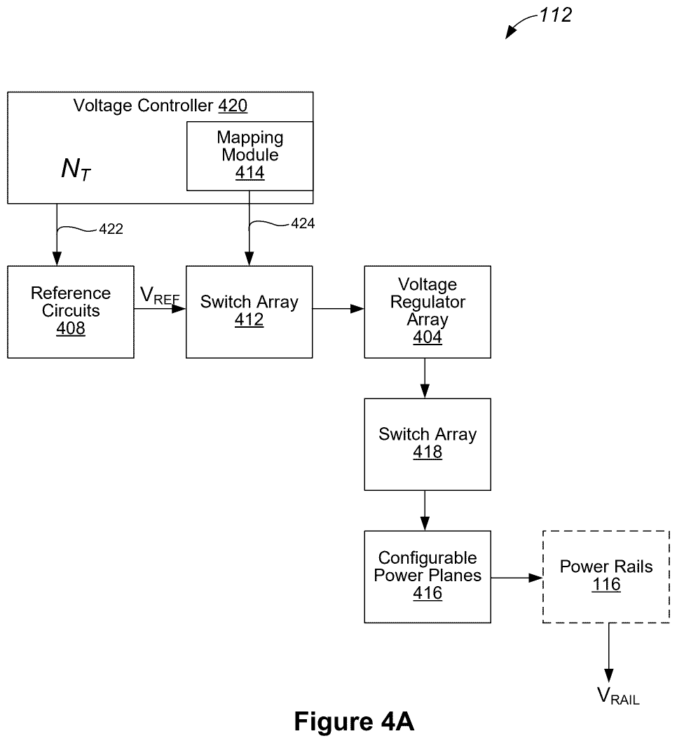

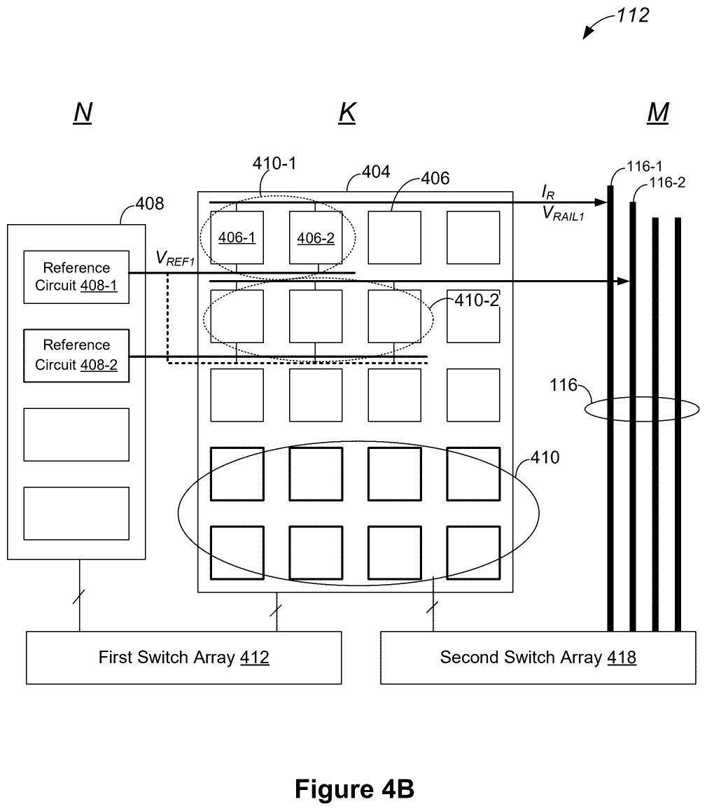

In some implementations, the PMIC module 112 includes a plurality of voltage regulator cells (e.g., voltage regulator cells 406 in FIG. 4B). In an example, a first PMIC chip 204-1 includes a subset of one or more respective voltage regulator cells (e.g., cell 406 in FIG. 4B), and is disposed immediately adjacent to an IO chip 206 including the I/O interface 106, allowing the I/O interface 106 to access a rail voltage provided by the subset of voltage regulator cells of the first PMIC chip 204-1. Alternatively, in some situations, two or more first PMIC chip 204-1 are disposed immediately adjacent to the IO chip 206 to provide the rail voltage to the IO chip 206 jointly. In another example, a memory chip 208 including one of the memory modules 104 is disposed on a location of the first surface 202A, and a second PMIC chip 204-2 is disposed a location of the second surface 202B aligned with (e.g., opposite to) the location of the first surface 202A. The second PMIC chip 204-2 includes a subset of one or more respective voltage regulator cells (e.g., cell 406 in FIG. 4B), and allows the one of the memory modules 104 to access a rail voltage provided by the respective voltage regulator cells vertically. By these means, a component of the SoC 120 may access its associated voltage regulator cell(s) located on a respective PMIC chip 204 that is disposed in proximity to the component without introducing an extended length to access a power rail 116, which helps reduce resistive and capacitive parasitics of the power rail 116 and enhance performance of the SoC 120.

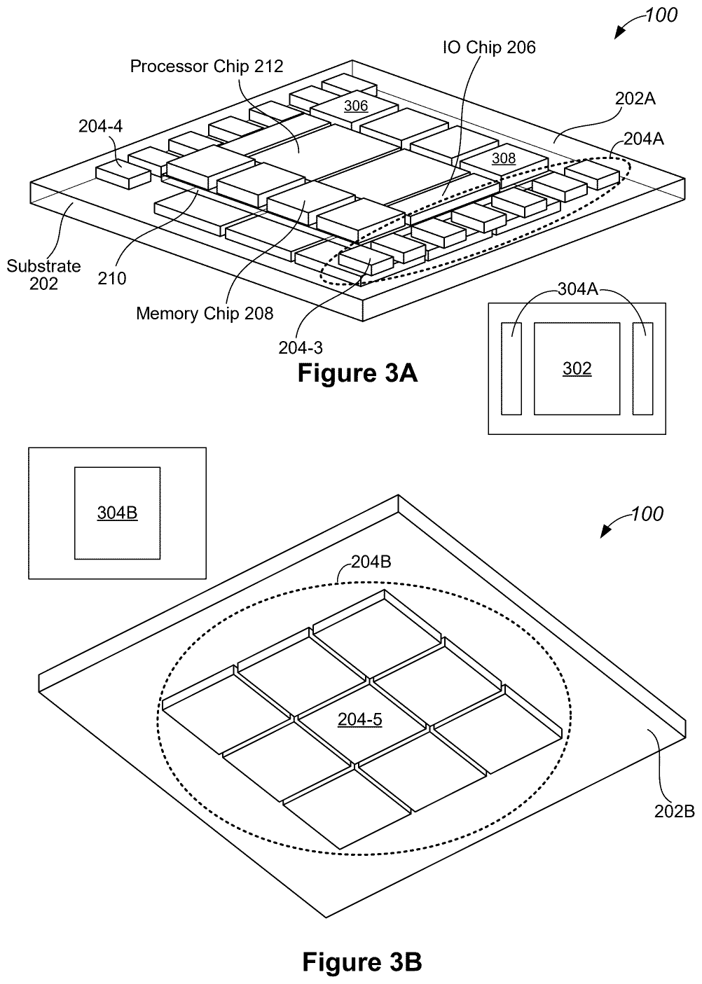

FIGS. 3A and 3B are a top perspective view and a bottom perspective view of another example electronic system 100, in accordance with some implementations, respectively. In some implementations, the first surface 202A of the substrate 202 includes a device region 302 on which a plurality of component chips (e.g., processor chip 212, IO chip 206, memory chips 208) are disposed. One or more first PMIC regions 304A (e.g., two PMIC regions) are located adjacent to the device region 302, and a first set of PMIC chips 204A are disposed on the one or more PMIC regions 304A of the first surface 202A of the substrate 202. For example, two rows of PMIC chips 204A are disposed adjacent to two opposing sides of the device region 302. In another example not shown, four rows of PMIC chips 204A are disposed adjacent to four distinct sides of the device region 302, respectively.

In some implementations not shown, the second surface 202B of the substrate 202 includes an alternative device region on which one or more component chips (e.g., processor chip 212, IO chip 206, memory chips 208) are disposed and one or more PMIC regions on which a second set of PMIC chips 204B are disposed, independently of a chip arrangement of the first surface 202A. Alternatively, in some implementations (FIG. 3B), the second surface 202B of the substrate 202 includes a second PMIC region 304B. Referring to FIG. 3A, the perspective view of the integrated electronic system 100 is depicted from the top angle with a see-through effect (e.g., to see through the substrate 202). In some implementations, the second PMIC region 304B at least partially overlaps the device region 302, allowing a component chip mounted on the device region 302 to access an output of the second PMIC region 304B using a via (e.g., a through silicon via (TSV)).

In some implementations, centers of the second PMIC region 304A and the device region 302 are aligned with one another, i.e., a center of the second PMIC region 304A and a center of the device region 302 are directly opposite to one another on two opposing surfaces 202A and 202B of the substrate 202. Further, in some implementations, sizes of the second PMIC region 304A and the device region 302 are equal to each other. Alternatively, in some implementations, the sizes of the second PMIC region 304A and the device region 302 are different from each other. Alternatively, in some implementations, the second PMIC region 304A and the device region 302 are independent from one another in size and/or in position.

In other words, the PMIC module 112 includes a plurality of voltage regulator cells distributed in a subset of the plurality of PMIC chips 204. Each PMIC chip 204 is located at a respective position on the first surface 202A or the second surface 202B of the substrate 202. In some implementations, the plurality of voltage regulator cells are grouped based on their locations to provide a plurality of rail voltages to a plurality of power rails 116 coupled to different components of the SoC 120. More specifically, in some implementations, each power rail 116 coupled to a component (e.g., CPU chip, GPU chip, memory chip, IO chip) is coupled to a set of voltage regulator cells, which are selected based on their locations with respect to a location of the component. For example, the set of voltage regulator cells are the closest to the respective component in distance compared with a remainder of the voltage regulator cells, thereby controlling associated resistive and capacitive parasitics. In another example, the set of voltage regulator cells, which coupled to the respective component, provides the lowest parasitic level. Among two voltage regulator cells having equal distances form the respective component, a voltage regulator cell located on the first surface 202A is selected over a voltage regulator cell located on the second surface 202B. In some implementations, a voltage regulator cell located on the first surface 202A and having a larger distance from the respective component is selected over a voltage regulator cell located on the second surface 202B and having a smaller distance from the respective component.

In some implementations, the PMIC module 112 further includes a plurality of reference circuits (e.g., circuit 408 in FIGS. 4A and 4B). The plurality of reference circuits may be formed on the same PMIC chip 204 or distributed on two or more PMIC chips 204. For example, each PMIC region 304A or 304B includes at least one PMIC chip 204 (e.g., chips 204-3, 204-4, and 204-5) dedicated to providing one or more reference circuits. In another example, all of the plurality of reference circuits used within the voltage regulator cells of the PMIC module 112 are consolidated on a single PMIC chip (e.g., chip 204-5).

Alternatively, in some implementations, the plurality of reference circuits used with the voltage regulator cells of the PMIC module 112 are provided by a single chip 306 or distributed among a plurality of chips (e.g., chips 306 and 308), which are mounted on, or integrated in, the device region 302.

FIG. 4A is a high-level block diagram of an example PMIC module 112, in accordance with some implementations, and FIG. 4B is a detailed block diagram of an example PMIC module 112, in accordance with some implementations. The PMIC module 112 includes, or is coupled to, a plurality of power rails 116 configured to provide one or more rail voltages V_{RAIL}. The PMIC module 112 further includes an array 404 of voltage regulator cells 406 and a plurality of reference circuits 408. The plurality of reference circuits 408 are coupled to, but distinct from, the array 404 of voltage regulator cells 406. The array 404 of voltage regulator cells 406 is coupled to the plurality of power rails 116, and configured to provide a plurality of voltage regulator sets 410. Each voltage regulator set 410 is configured to output a respective rail voltage V_{RAIL} to a respective power rail 116. Each of the plurality of reference circuits 408 is shared by, and configured to provide a respective reference voltage V_{REF} to, one or more respective voltage regulator cells 406 of a respective voltage regulator set 410. The respective voltage regulator set 410 is configured to generate the respective rail voltage V_{RAIL} based on the respective reference voltage V_{REF}.

Stated another way, some implementations of this application include a PMIC module 112 that has an array 404 of voltage regulator cells 406, a plurality of voltage references 408 that are selectable and programmable, and distribution circuits and buses that are selectable. Different numbers of voltage regulator cells 406 may be grouped together to form a voltage regulator set 410 for outputting a rail voltage V_{RAIL} (also called a power supply voltage). The array 404 of voltage regulator cells 406 may be grouped to form a single voltage regulator set 410 or a plurality of power regulator sets 410, thereby providing a single rail voltage V_{RAIL} or multiple rail voltages V_{RAIL}. In some implementations, the PMIC module 112 provides a plurality of rail voltages V_{RAIL} correspond to a plurality of distinct voltage regulator sets 410, and each voltage regulator set 410 includes a respective number of voltage regulator cells 406, independently of other voltage regulator set(s) 410. For each voltage regulator set 410, outputs of the respective voltage regulator cells 406 are electrically coupled (e.g., shortened) to one another and further to a respective power rail 116. In some implementations, a voltage regulator set 410 is configured to output a variable rail voltage V_{RAIL}, e.g., to track a respective reference voltage V_{REF}.

In some implementations, the PMIC module 112 includes, or is coupled to, a single substrate (e.g., substrate 202 in FIGS. 2A and 2B). The array 404 of voltage regulator cells 406 and the plurality of reference circuits 408 are disposed on the substrate 202, separately from one another. In some implementations, the array 404 of voltage regulator cells 406 and the plurality of reference circuits 408 correspond to different sets of PMIC chips 204 disposed on PMIC regions 304A and 304B (FIGS. 3A and 3B) of the substrate 202. Alternatively, in some implementations, the array 404 of voltage regulator cells 406 is distributed in PMIC chips 204 disposed on the PMIC regions 304A and 304B of the substrate 202, and the plurality of reference circuits 408 correspond to chips (e.g., chip 306 or 308 in FIG. 3A) disposed on a device region 302 (FIG. 3A) of the substrate 202.

Referring to FIG. 4B, in some implementations, the plurality of power rails 116 include a first number M of power rails 116, and the plurality of reference circuits 408 include a second number N of reference circuits 408. The second number N is equal to or less than the first number M. Further, in some implementations, each reference circuit 408 and a respective power rail 116 is uniquely associated with each other, and the respective reference circuit 408 is configured to provide the respective reference voltage V_{REF} to the respective voltage regulator cell set 410 assigned to generate the rail voltage V_{RAIL} for the power rail 116. A number of voltage regulator cells 406 in the respective voltage regulator cell set 410 may be varied.

In some implementations, rail voltages V_{RAIL} of two power rails 116-1 and 116-2 are equal to each other, and each power rail 116 maintains a consistent voltage. It is required that voltage regulator cells 406 contributing to each respective power rail 116-1 or 116-2 be driven by the same respective reference circuit 408. Further, in some implementations, two voltage regulator sets 410-1 and 410-2 corresponding to the two power rails 116-1 and 116-2 are coupled to two distinct reference circuits 408-1 and 408-2. Alternatively, in some implementations, the two voltage regulator sets 410-1 and 410-2 corresponding to the two power rails 116-1 and 116-2 are coupled to the same reference circuit 408 (e.g., 408-1). As such, the second number N of the reference circuits 408 is equal to or less than the first number M of the power rails 116.

In some implementations, the plurality of power rails 116 include a first number M of power rails 116, and the plurality of reference circuits 408 include a second number N of reference circuits 408. The array 404 of voltage regulator cells 406 includes a third number K of voltage regulator cells 406. The second number N is equal to or less than (≤) the third number K, and the first number M is equal to or less than (≤) the third number K.

In some implementations, the PMIC module 112 includes a first switch array 412 (e.g., having the second number N of rows and the third number K of columns, or the second number N of columns and the third number K of rows). For example, rows of the first switch array 412 are electrically coupled to the second number N of reference circuits 408, and columns of the first switch array 412 are electrically coupled to the third number K of voltage regulator cells 406 of the array 404. Each row-column cross section of the first switch array 412 includes a switch component configured to control coupling of a respective reference circuit 408 and a respective voltage regulator cell 406. For each voltage regulator set 410 (e.g., set 410-1 in FIG. 4B), a respective set of switch components of the first switch array 412 are enabled to couple the respective reference circuit 408 (e.g., circuit 408-1) to the one or more respective voltage regulator cells 406 (e.g., cells 406-1 and 406-2). Note that, in some implementations, lines connecting the reference circuits 408-1 and 408-2 directly to the voltage regulator cells 406 in the voltage regulator sets 410-1 and 410-2 may not correspond to interconnects and are drawn in FIG. 4B merely for illustrative purposes.

Referring back to FIG. 4A, in some implementations, the PMIC module 112 further includes a mapping module 414 coupled to the first switch array 412. The mapping module 414 is configured to control the switch components of the first switch array 412 to group the voltage regulator cells 406 to form the plurality of voltage regulator sets 410. More specifically, the mapping module 414 is configured to determine whether to enable or disable each of the switch components of the first switch array 412.

In some implementations, the PMIC module 112 further includes a plurality of configurable power planes 416 embedded in a module substrate of the PMIC module 112 or a substrate 202 to which the PMIC module 112 is mounted. Each of the plurality of power rails 116 is electrically coupled to a respective power plane 416, and extends to one or more electrical components (e.g., modules 102-108) to provide a respective rail voltage V_{RAIL} to these components. Each output of voltage regulator cells 406 of a respective voltage regulator set 410 is also electrically coupled to the respective power plane 416, providing the power voltage V_{RAIL} to the respective power plane 416.

Further, referring to FIG. 4B, in some implementations, the PMIC module 112 includes a second switch array 418 (e.g., having the first number M of rows and the third number K of columns, or the first number M of columns and the third number K of rows). For example, rows of the first switch array 412 are electrically coupled to the first number M of power rails 116 or configurable power planes 416, and columns of the second switch array 418 are electrically coupled to outputs of the third number K of voltage regulator cells 406 of the array 404. Each row-column cross section of the second switch array 418 includes a switch component configured to control coupling a respective voltage regulator cell 406 to a respective configurable power plane 416 or to a respective power rail 116. For each voltage regulator set 410 (e.g., set 410-1 in FIG. 4B), a respective set of switch components of the first switch array 412 are enabled to couple the one or more respective voltage regulator cells 406 (e.g., cells 406-1 and 406-2) to the a respective configurable power plane 416 or to the respective power rail 116 (e.g., rail 116-1). Additionally, in some implementations, the second switch array 418 and the first switch array 412 are integrated in a single switch array.

Note that, in some implementations, lines connecting the power rails 116-1 and 116-2 directly to the voltage regulator cells 406 in the voltage regulator sets 410-1 and 410-2 may not correspond to interconnects and are drawn in FIG. 4B merely for illustrative purposes.

In some implementations, the plurality of voltage regulator sets 410 include a first voltage regulator set 410-1 that is configured to output a first rail voltage V_{RAIL1} (e.g., 1.2V, 0.8V) to a first power rail 116-1, and the first rail voltage is equal to a first reference voltage V_{REF1} provided by a first reference circuit 408-1. Stated another way, an output voltage level of each voltage regulator set 410 is set by its associated reference voltage, and the voltage regulator set 410 is configured to track its associated reference voltage provided by a respective reference circuit 408.

Referring back to FIG. 4A, in some implementations, the PMIC module 112 further includes a voltage controller 420 coupled to the plurality of reference circuits 408. The voltage controller 420 is configured to generate a digital control signal 422 based on the first rail voltage associated with the first power rail 116-1 and provide the digital control signal 422 to the first reference circuit 408-1 defining the first reference voltage V_{REF1}. The first power rail 116-1 extends to one or more electrical components (e.g., modules 102-108) to provide the first rail voltage to these components. Characteristics of the first power rail 116-1 (e.g., rail current, rail voltage) are determined based on operation of the one or more electrical components. The first reference voltage of the first reference circuit 408-1 is further determined and set based on the characteristics of the first power rail 116-1. In some implementations, the plurality of reference circuits 408 are identical to one another. The digital control signal 422 determines magnitudes of the reference voltages V_{REF} outputted by the plurality of reference circuits 408. Conversely, in some implementations, at least two of the plurality of reference circuits 408 are different from one another. In an example, each reference circuit 408 includes a digital-to-analog converter (DAC).

Additionally, in some implementations, the first voltage regulator set 410-1 further includes a target number N_{T} (e.g., 2) of voltage regulator cells 406 and is configured to deliver up to a predefined rail current I_{RAIL} to the first power rail 116-1. The target number N_{T} is determined based on the predefined rail current I_{RAIL}, e.g., equal to the predefined rail current I_{RAIL} divided by a regulator current I_{VGC} that is deliverable by each voltage regulator cell 406. Additionally, in some implementations, the PMIC module 112 further includes a voltage controller 420 coupled to the array 404 of voltage regulator cells 406. The voltage controller 420 is configured to determine the target number N_{T} based on the predefined rail current I_{RAIL} associated with the first power rail 116-1, generate one or more select signals 424 based on the target number N_{T}, and provide the one or more select signals 424 to the array 404 of voltage regulator cells 406 to select the target number N_{T} of voltage regulator cells 406 (e.g., cells 406-1 and 406-2) of the first voltage regulator 116-1. In some implementations, the mapping module 414 is part of the voltage controller 420.

In some implementations, voltage regulator cells 406 in the array 404 of voltage regulator cells 406 are identical to each other. An output voltage of each voltage regulator cell 406 is determined based on a respective reference voltage V_{REF} received by the respective voltage regulator cell 406. The higher a rail current I_{RAIL} of a power rail 116, the larger the target number N_{T} of the voltage regulator cells 406 grouped to drive the power rail 116.

Conversely, in some implementations, at least two voltage regulator cells 406 in the array 404 of voltage regulator cells 406 are different from one another. For example, an output voltage of each voltage regulator cell 406 is determined based on a respective reference voltage V_{REF} received by the respective voltage regulator cell 406. The two voltage regulator cells 406 may have different driving capabilities (e.g., different regulator currents). Different numbers of the two voltage regulator cells 406 may be selected and combined based on a rail current I_{RAIL} associated with a power rail 116 and regulator currents I_{VGC} of the two voltage regulator cells 406.

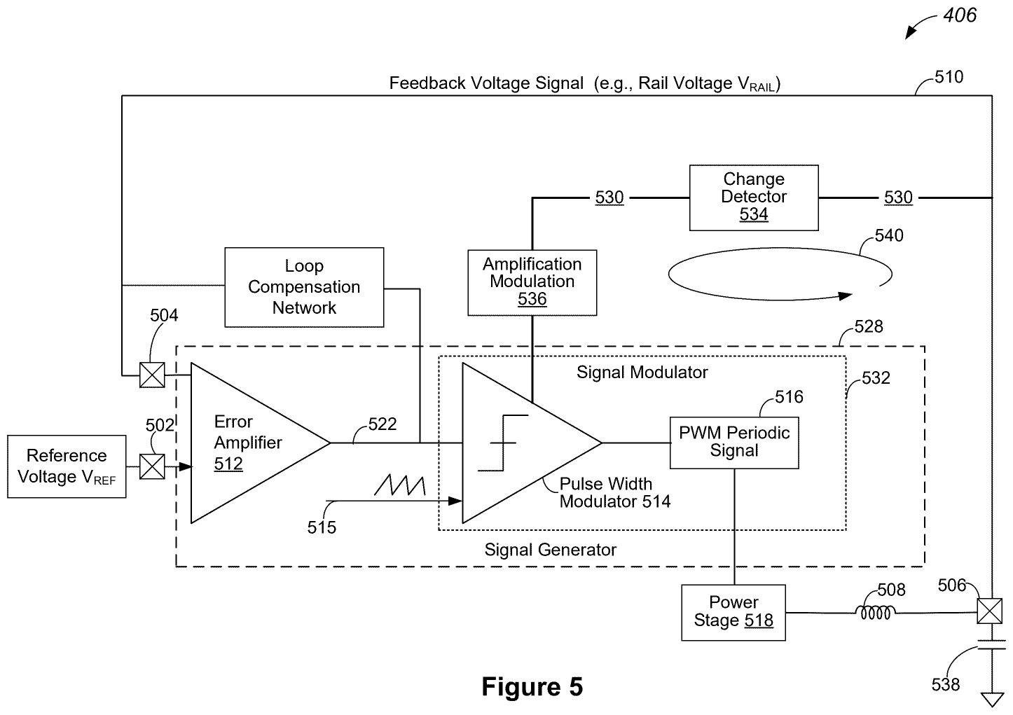

FIG. 5 is a schematic diagram of an example voltage regulator cell 406, in accordance with some implementations. In some implementations, the voltage regulator cell 406 includes an input reference interface 502 for receiving a target reference voltage V_{REF}, an input signal interface 504 for receiving an input signal (e.g., rail voltage V_{RAIL}), an output interface 506 for providing a rail voltage V_{RAIL} to a power rail (e.g., power rail 116-1 in FIG. 4B), a first feedback path 510 coupling the output interface 506 of the voltage regulator cell 406 to the input signal interface 504 of the voltage regulator cell 406, and an inductor 508 electrically coupled between the input signal interface 504 and the output interface 506.

In some implementations, the voltage regulator cell 406 includes an error amplifier 512, a pulse width modulator 514, a power stage 518, and the feedback path 510. The error amplifier 512 is configured to receive a reference voltage V_{REF} and a rail voltage V_{RAIL} and generate an amplified difference signal 522. The pulse width modulator 514 is coupled to the error amplifier 512 configured to generate a pulse width modulated (PWM) periodic signal 516 having a pulse width and a feature frequency f. In an example, the pulse width modulator 514 includes a comparator, and receives an input signal 515 having a Sawtooth waveform or a triangular waveform. The pulse width modulator 514 is coupled to the error amplifier 512 and configured to modulate the pulse width of the input signal 515. The power stage 518 is coupled to the pulse width modulator 514 and configured to generate the rail voltage V_{RAIL} based on the PWM periodic signal 516. In an example, the power stage 518 includes one or more power field effect transistors (FETs). The feedback path 510 is configured to couple an output of the power stage 518 to an input of the error amplifier 512, e.g., jointly with an inductor 508.

In some implementations, the voltage regulator cell 406 includes a signal generator 528, a power stage 518, and a first feedback path 510 coupling an output of the power stage to a signal input of the signal generator 528. The signal generator 528 is configured to receive a target reference voltage V_{REF} and a rail voltage V_{RAIL} and generate a PWM periodic signal 516 having a target pulse width. The power stage 518 is coupled to the signal generator 528 and configured to generate the rail voltage based on the PWM periodic signal 516 having the target pulse width. Further, in some implementations, in the voltage regulator cell 406, a second feedback path 530 couples the output of the power stage 518 to a signal modulator 532 of the signal generator 528. The second feedback path 530 is configured to pull the rail voltage V_{RAIL} back to the target reference voltage V_{REF} when the rail voltage V_{RAIL} deviates from the target reference voltage V_{REF} at a deviation rate higher than a characteristic circuit rate of the voltage regulator cell 406.

Further, in some implementations, the second feedback path 530 further includes a change detector 534 and an amplification and modulation circuit 536. The change detector 534 is coupled to the output of the power stage 518, and configured to detect the rail voltage V_{RAIL} deviating from the target reference voltage V_{REF} at the deviation rate. The amplification and modulation circuit 536 is coupled to the change detector 534 and the signal modulator 532, and configured to adjust a pulse width of the PWM periodic signal 516 in real-time, when the rail voltage V_{RAIL} deviates from the target reference voltage V_{REF} at the deviation rate. In other words, in some implementations, the change detector 534 is configured to sense fast voltage changes in the feedback voltage signal in the first feedback path 510 (e.g., corresponding to fast voltage changes in an output of the voltage regulation cell 406). The change detector 534 generates a modulation signal to modulate the signal modulator 532, thereby preventing an output of the voltage regulator cell 406 from deviating from the reference voltage V_{REF}.

State another way, in some implementations, the voltage regulation cell 406 is implemented based on a regulation control loop using one or more of a power stage 518, an integrated on-chip inductor 508, and a feedback voltage signal (e.g., carrying rail voltage V_{RAIL} in a first feedback path 510). The regulation control loop tracks a difference between voltage feedback signal and the selected reference voltage V_{REF}, and generates pulse width modulated signals (e.g., PWM periodic signal 516) driving the power stage 518. The output of the power stage 518 may drive an integrated on-chip inductor 508.

In some implementations, an inductor 508 and an output filter capacitor 538 forms an output filter. The output filter may be part of, or external to, a respective voltage regulator cell 406. The output filter may partially belong to a respective voltage regulator cell 406. The output filter capacitor 538 may be embedded in a GPU or CPU package substrate, a substrate of the SoC 120 (e.g., substrate 202), or a processor chip 212 (FIG. 2A). In some implementations, for a voltage regulator set 410, output terminals of on-chip inductors 508 of voltage regulator cells 406 of the voltage regulator set 410 correspond to the output interface 506, and are coupled via interconnects to an output filter capacitor 538, which may be external to the voltage regulator cells 406. Stated another way, the voltage regulator cells 406 of the voltage regulator set 410 share, and is routed separately via the interconnects to, a common output filter capacitor 538. Further, in some implementations, the feedback voltage signal carried by the feedback path 510 is connected to the output filter capacitor via the interconnects extending external to the voltage regulator cells 406.

Additionally, in some implementations, a regulation control mechanism of a voltage regulator cell 406 employs dual control loops including the regulation control loop and a transient modulation loop 540. The regulation control loop is based on the first feedback path 510, and configured to modulate the PWM periodic signal 516 based on an error signal (e.g., amplified difference signal 522) generated by integrating a difference between the reference voltage V_{REF} and the feedback voltage signal. In some implementations, the regulation control loop integrates a difference between the reference voltage V_{REF} and the feedback voltage signal, and includes a signal modulator 532, which is shared with the transient modulation loop 540. The amplified difference signal 522 reflects integration of the difference between the reference voltage V_{REF} and the feedback voltage signal, and is applied to modulate the PWM periodic signal 516 and generate a rail voltage V_{RAIL} to be outputted at the output interface 506 of the voltage regulator cell 406. The rail voltage V_{RAIL} settles at the associated reference voltage V_{REF}. Additionally, the transient modulation loop 540 is configured to modulate the PWM periodic signal 516 based on detection of transient characteristics of the feedback voltage signal (e.g., the rail voltage V_{REF}).

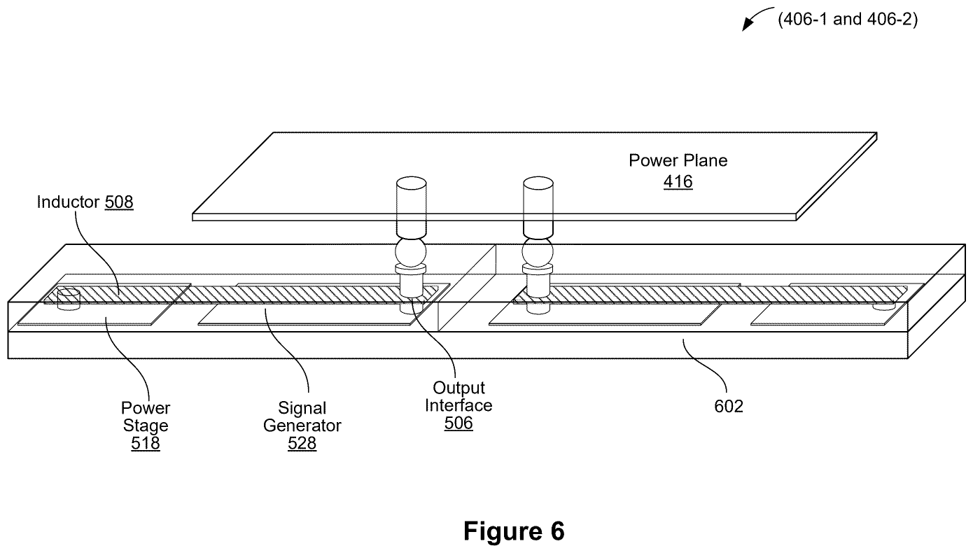

FIG. 6 is a conceptual diagram illustrating example two voltage regulator cells 406-1 and 406-2 (also shown in FIG. 4B) for providing a rail voltage V_{RAIL}, in accordance with some implementations. Each of the two voltage regulator cells 406-1 and 406-2 includes a respective inductor 508 electrically coupled to an output interface 506 of the respective voltage regulator cell 406. In some implementations, for each voltage regulator cell 406-1 or 406-2, the respective inductor 508 is integrated on chip, e.g., monolithically formed on a respective PMIC chip 204. In some implementations, a configurable power plane 416 is embedded in a module substrate of a PMIC module 112 or a substrate 202 of the SoC 120 to which a PMIC module 112 is mounted. The two voltage regulator cells 406-1 and 406-2 may be formed on a common chip substrate 602 or on two distinct chip substrates 602. The output interfaces 506 of the two voltage regulator cells 406-1 and 406-2 are electrically coupled to the power plane 416, which is further coupled to a power rail 116 (not shown on FIG. 6).

In some implementations, the inductor 508 is integrated on the cell substrate 602, e.g., above the signal generator 528, the power stage 518, and/or any other circuits 408, 412, 418, or 420 of the PMIC module 112. An input terminal of the inductor 508 is coupled to an output of the power stage 518, e.g., using a via, a metallic layer, a solder ball, a redistribution layer (RDL), or a combination thereof. In an example, an output terminal of the inductor 508 corresponds to an output of the inductor 508, and is connected to an interconnect that couples the inductor 508 to a bump or a solder ball of the PMIC module 112. The bump or solder ball is applied to electrically couple the PMIC module 112 to other electrical components (e.g., components 102-108) of an SoC 120. In some implementations, each of two terminals of the inductor 508 includes a respective interconnect made of a via, a metallic layer, an RDL, or a combination thereof, and is configured to provide a Kelvin sensing point.

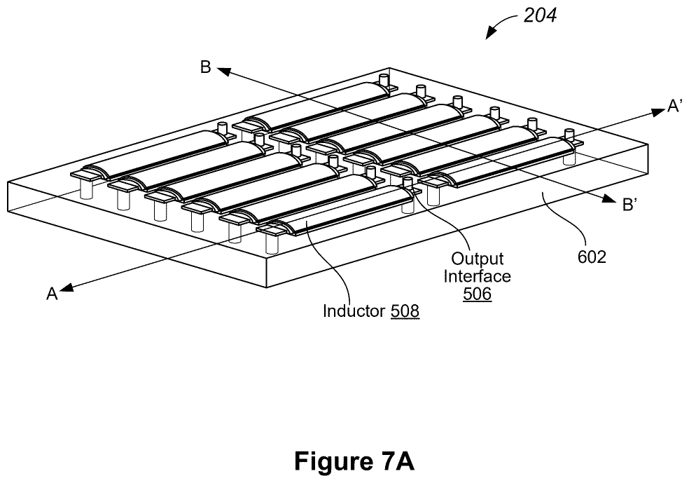

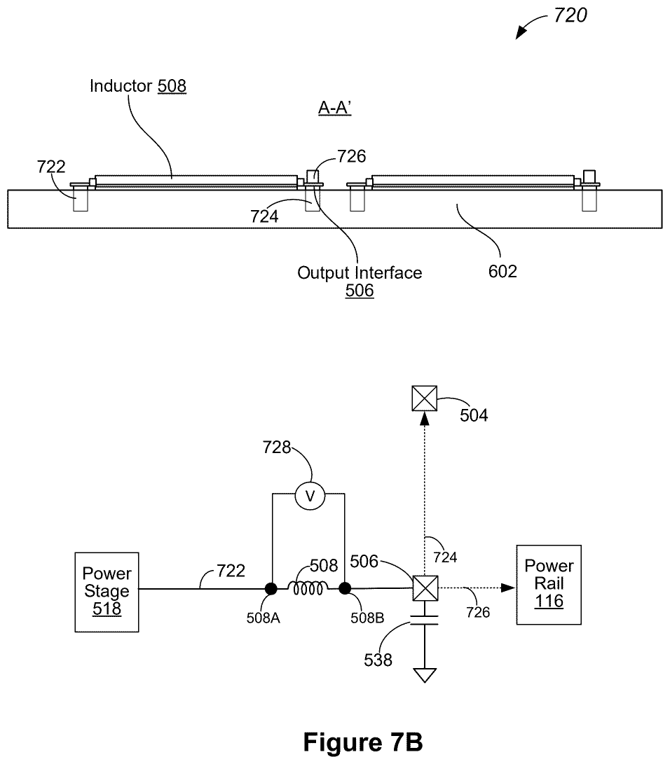

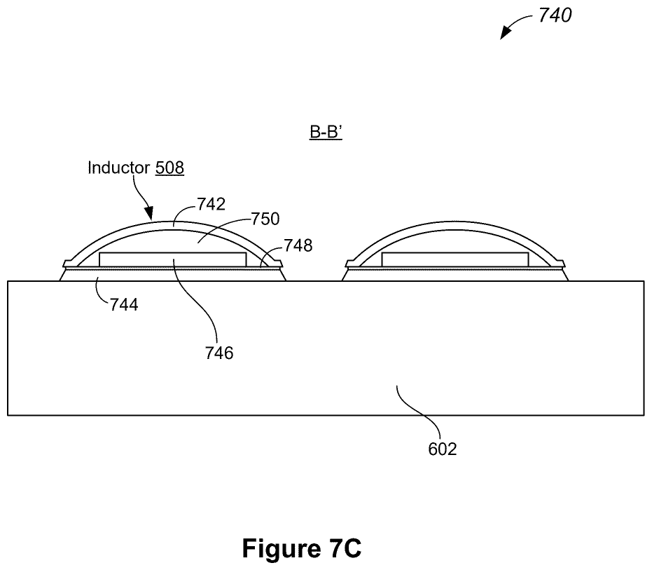

FIG. 7A is a perspective view of an example PMIC chip 204 including a plurality of inductors 508 coupled in a plurality of voltage regulator cells 406, in accordance with some implementations, and FIGS. 7B and 7C are two cross sectional views 720 and 740 of a portion of the PMIC chip 204 shown in FIG. 7A including two inductors 508 of two voltage regulator cells 406, in accordance with some implementations. The PMIC chip 204 has a chip substrate 602 and includes twelve voltage regulator cells 406 formed monolithically on a top surface of the chip substrate 602. Each voltage regulator cell 406 includes a respective inductor 508 integrated on the top surface of the chip substrate 602. Stated another way, the voltage regulator cells 406 (e.g., transistors and metal interconnects) may be formed on the cell substrate 602 and partially underneath the inductor 508. The PMIC chip 204 includes two cross sections AA′ and BB′ that are perpendicular to one another and to the top surface of the chip substrate 602. The cross section AA′ is shown in FIG. 7B, and part of the cross section BB′ is shown in FIG. 7C.

Referring to FIG. 7B, in some implementations, an inductor 508 includes three vias 722, 724, and 726. A first via 722 is coupled between an output a power stage 518) of a respective voltage regulator cell 406 to an input terminal 508A of the inductor 508, driving current toward the inductor 508. In some implementations, a second via 724 is coupled between an output terminal 508B of the respective inductor 508. The output terminal 508B of the respective inductor 508 corresponds to an output port 506 of the voltage regulator cell 406. Alternatively, in some implementations, the second via 724 is coupled between the output terminal 508B of the respective inductor 508 and an input signal interface 504 (FIG. 5). A third via 726 is coupled between the output terminal 508B of the inductor 508 and a power rail 116 powering other components (e.g., components 102-108 in FIG. 1) of an SoC 120, providing current and power to enable operations of the other components of the SoC 120. In some implementations, the third via 726 couples the output terminal 508B of the inductor 508 to the power rail 116 via a configurable power plane 416 (FIG. 6). In some implementations, the third via 726 is vertically aligned with the second via 724. In some implementations not shown, the third via 726 is laterally shifted (i.e., not vertically aligned) with respect to the second via 724.

In some embodiments, the first via 722 and the second via 724 enable Kelvin connections for sensing a current passing a conduction trace of the inductor 508. A current sensing circuit 728 is coupled to the input terminals 508A and the output terminal 508B of the inductor 508, and configured to measure a voltage drop on the inductor 508. Given that a resistance of the inductor 508 is known, the voltage drop is applied to determine a current passing through the inductor 508.

In some implementations, each of two terminals 508A and 508B of the inductor 508 includes a respective interconnect made of a via, a metallic layer, an RDL, or a combination thereof. The respective interconnect forms a Kelvin connection, which may be coupled to a current sensing circuit associated with the voltage regulator cell 406 for sensing an inductor current running through the inductor 508. In some implementations, a distance between Kelvin connections of each voltage regulator cell 406 is substantially uniform in the array 404 of voltage regulator cells 406 (e.g., in FIG. 7A). For each voltage regulator set 410, current balancing among different voltage regulator cells 406 is enabled using a single shared reference circuit 408.

Referring to FIG. 7C, in some implementations, the inductor 508 is formed on top of the cell substrate 602 (e.g. a silicon substrate), and include at least two laminated magnetic thin film layers 742 and 744 wrapping around a conductor 746. The inductor 508 further includes an insulation film layer 748 and a dielectric filling structure 750. The two laminated magnetic thin film layers 742 and 744 are electrically isolated from the conductor 746 by the insulation film layer 748 and a dielectric filling structure 750. In some implementations, there is no gap in an enclosure formed by the two laminated magnetic thin film layers 742 and 744. Conversely, in some implementations, there is a gap in the enclosure formed by the two laminated magnetic thin film layers 742 and 744. Further, in some implementations, each of the two laminated magnetic thin film layers 742 and 744 includes a stack of alternating magnetic thin films and dielectric thin films.

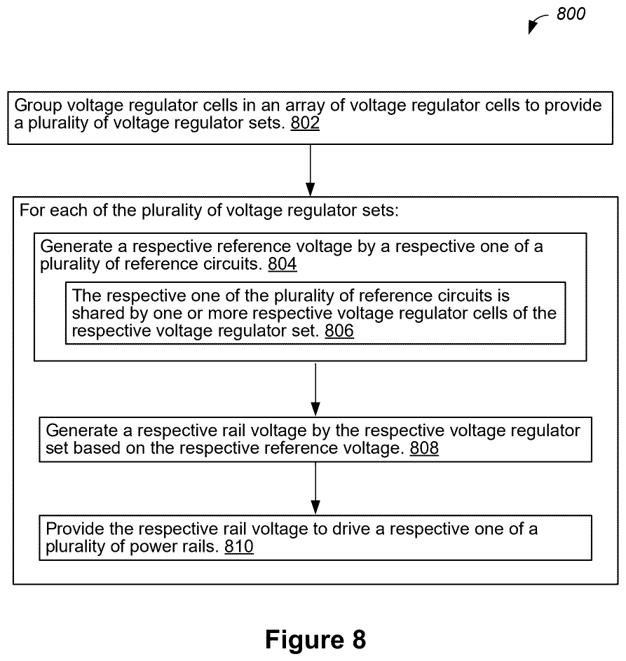

FIG. 8 is a flow diagram of an example method 800 for providing rail voltages V_{RAIL} for an electronic system 100, in accordance with some implementations. The method 800 is implemented by an electronic system 100 (e.g., in FIG. 1-3B). The electronic system 100 groups (operation 802) voltage regulator cells 406 in an array 404 of voltage regulator cells 406 to provide a plurality of voltage regulator sets 410. For each of the plurality of voltage regulator sets 410, the electronic system 100 generates (operation 804) a respective reference voltage V_{REF} by a respective one of a plurality of reference circuits 408. The respective one of the plurality of reference circuits 408 is shared (operation 806) by one or more respective voltage regulator cells 406 of the respective voltage regulator set 410. The respective voltage regulator set 410 generates (operation 808) a respective rail voltage V_{RAIL} based on the respective reference voltage V_{REF}. The electronic system provides (operation 810) the respective rail voltage V_{RAIL} to drive a respective one of a plurality of power rails 116.

In some implementations, the electronic system 100 includes a substrate 202, and the array 404 of voltage regulator cells 406 and the plurality of reference circuits 408 are disposed on the substrate, separately from one another.

In some implementations, the electronic system 100 includes a substrate, and the array 404 of voltage regulator cells 406 and the plurality of reference circuits 408 are formed by semiconductor manufacturing on the top surface of the substrate. The array 404 of voltage regulator cells 406 and the plurality of reference circuits 408 are formed on two different chip areas of the substrate. In other words, each voltage regulator cell 406 does not have a separate and dedicated reference circuit 408 locally within the voltage regulator cell 406.

Each of the above identified elements may be stored in one or more memory devices, and corresponds to a set of instructions for performing a function described above. The above identified modules or programs (i.e., sets of instructions) need not be implemented as separate software or firmware programs, procedures, modules or data structures, and thus various subsets of these modules may be combined or otherwise re-arranged in various implementations. In some implementations, the memory, optionally, stores a subset of the modules and data structures identified above. Furthermore, the memory, optionally, stores additional modules and data structures not described above.

Various examples of aspects of the disclosure are described as numbered clauses (1, 2, 3, etc.) for convenience. These are provided as examples, and do not limit the subject technology. Identifications of the figures and reference numbers are provided below merely as examples and for illustrative purposes, and the clauses are not limited by those identifications.

Clause 1. An electronic system, comprising: an array of voltage regulator cells, wherein the array of voltage regulator cells is configured to provide a plurality of voltage regulator sets, and each voltage regulator set is configured to output a respective rail voltage and provide the respective rail voltage to a respective power rail of a plurality of power rails; and a plurality of reference circuits coupled to the array of voltage regulator cells, wherein each of the plurality of reference circuits is shared by, and configured to provide a respective reference voltage to, one or more respective voltage regulator cells of a respective voltage regulator set, and the respective voltage regulator set is configured to generate the respective rail voltage based on the respective reference voltage.

Clause 2. The electronic system for clause 1, further comprising a substrate, wherein the array of voltage regulator cells and the plurality of reference circuits are disposed on the substrate, separately from one another.

Clause 3. The electronic system of clause 1 or 2, wherein the plurality of power rails include a first number of power rails, and the plurality of reference circuits include a second number of reference circuits, the second number equal to or less than the first number.

Clause 4. The electronic system of any of clauses 1-3, wherein each of the plurality of power rails is uniquely associated with a distinct one of the plurality of reference circuits, which is configured to provide the respective reference voltage to each voltage regulator cell in the respective voltage regulator set.

Clause 5. The electronic system of any of clauses 1-4, wherein: the plurality of power rails include a first number of power rails; the plurality of reference circuits include a second number of reference circuits; the array of voltage regulator cells includes a third number of voltage regulator cells; the second number is equal to or less than (≤) the third number; and the first number is equal to or less than (≤) the third number.

Clause 6. The electronic system of any of clauses 1-5, wherein the plurality of voltage regulator sets include a first voltage regulator set that is configured to output a first rail voltage to a first power rail, and the first rail voltage is equal to a first reference voltage provided by a first reference circuit.

Clause 7. The electronic system of clause 6, further comprising a voltage controller coupled to the plurality of reference circuits, wherein the voltage controller is configured to generate a digital control signal based on the first rail voltage associated with the first power rail and provide the digital control signal to the first reference circuit defining the first reference voltage.

Clause 8. The electronic system of clause 6, wherein: the first voltage regulator set further includes a target number of voltage regulator cells and is configured to deliver up to a predefined regulator current to the first power rail; and the target number is determined based on the predefined regulator current.

Clause 9. The electronic system of clause 8, further comprising a voltage controller coupled to the array of voltage regulator cells; wherein the voltage controller is configured to determine the target number based on the predefined regulator current associated with the first power rail, generate one or more select signals based on the target number, and provide the one or more select signals to the array of voltage regulator cells to select the target number of voltage regulator cells of the first voltage regulator.

Clause 10. The electronic system of any of clauses 1-9, wherein voltage regulator cells in the array of voltage regulator cells are identical to each other.

Clause 11. The electronic system of any of clauses 1-9, wherein at least two voltage regulator cells in the array of voltage regulator cells are different from one another.

Clause 12. The electronic system of any of clauses 1-11, wherein the plurality of reference circuits are identical to one another.

Clause 13. The electronic system of any of clauses 1-12, wherein a first voltage regulator cell further comprises: a first signal generator configured to receive a target reference voltage and a first rail voltage and generate a periodic signal having a target pulse width; and a first power stage coupled to the first signal generator and configured to generate the first rail voltage based on the periodic signal having the target pulse width; and a first feedback path coupling an output of the first power stage to a signal input of the first signal generator.

Clause 14. The electronic system of clause 13, wherein the first voltage regulator cell further comprises: a second feedback path coupling the output of the first power stage to a signal modulator of the first signal generator, the second feedback path configured to pull the first rail voltage back to the target reference voltage when the first rail voltage deviates from the target reference voltage at a deviation rate higher than a characteristic circuit rate of the first voltage regulator cell.

Clause 15. The electronic system of clause 14, wherein the second feedback path further comprises: a change detector coupled to the output of the first power stage, the change detector configured to detect the first rail voltage deviating from the target reference voltage at the deviation rate; and an amplification and modulation circuit coupled to the change detector and the signal modulator, the amplification and modulation circuit configured to adjust a pulse width of the periodic signal in real-time, when the first rail voltage deviates from the target reference voltage at the deviation rate.

Clause 16. The electronic system of any of clauses 1-12, wherein each voltage regulator cell further comprises: an error amplifier configured to receive the respective reference voltage and the respective rail voltage and generate an amplified difference signal; a pulse width modulator coupled to the error amplifier and configured to generate a periodic signal having a pulse width and a feature frequency; and a power stage coupled to the pulse width modulator and configured to generate the respective rail voltage based on the periodic signal; and a feedback path coupling an output of the power stage to an input of the error amplifier.

Clause 17. The electronic system of any of clauses 1-12, wherein a first voltage regulator cell further comprises: an input reference interface for receiving a target reference voltage; an input signal interface for receiving an input signal; an output interface for providing a first rail voltage to a first rail; a first feedback path coupling the output interface of the first voltage regulator cell to the input signal interface of the first voltage regulator cell; and an inductor electrically coupled between the input signal interface and the output interface.

Clause 18. The electronic system of clause 17, wherein the inductor includes one of an integrated inductor formed on a substrate of an integrated circuit including a subset of the array of voltage regulator cells or a hybrid inductor assembled onto the substrate.

Clause 19. An apparatus, comprising: a plurality of power rails configured to providing one or more rail voltages; and an electronic system in any of clauses 1-18.

Clause 20. An integrated circuit, comprising: a plurality of power rails configured to providing one or more rail voltages; and an electronic system in any of clauses 1-18.

Clause 21. A power management integrated circuit (PMIC), comprising an electronic system in any of clauses 1-18.

Clause 22. A method, comprising: grouping voltage regulator cells in an array of voltage regulator cells to provide a plurality of voltage regulator sets; and for each of the plurality of voltage regulator sets: generating a respective reference voltage by a respective one of a plurality of reference circuits, wherein the respective one of the plurality of reference circuits is shared by one or more respective voltage regulator cells of the respective voltage regulator set; generating a respective rail voltage by the respective voltage regulator set based on the respective reference voltage; and providing the respective rail voltage to drive a respective one of a plurality of power rails, wherein the method is implemented by an electronic system in any of clauses 1-18.

The terminology used in the description of the various described implementations herein is for the purpose of describing particular implementations only and is not intended to be limiting. As used in the description of the various described implementations and the appended claims, the singular forms “a”, “an” and “the” are intended to include the plural forms as well, unless the context clearly indicates otherwise. It will also be understood that the term “and/or” as used herein refers to and encompasses any and all possible combinations of one or more of the associated listed items. It will be further understood that the terms “includes,” “including,” “comprises,” and/or “comprising,” when used in this specification, specify the presence of stated features, integers, steps, operations, elements, and/or components, but do not preclude the presence or addition of one or more other features, integers, steps, operations, elements, components, and/or groups thereof. Additionally, it will be understood that, although the terms “first,” “second,” etc. may be used herein to describe various elements, these elements should not be limited by these terms. These terms are only used to distinguish one element from another.

As used herein, the term “if”' is, optionally, construed to mean “when” or “upon” or “in response to determining” or “in response to detecting” or “in accordance with a determination that,” depending on the context. Similarly, the phrase “if it is determined” or “if [a stated condition or event] is detected” is, optionally, construed to mean “upon determining” or “in response to determining” or “upon detecting [the stated condition or event]” or “in response to detecting [the stated condition or event]” or “in accordance with a determination that [a stated condition or event] is detected,” depending on the context.

The foregoing description, for purpose of explanation, has been described with reference to specific implementations. However, the illustrative discussions above are not intended to be exhaustive or to limit the claims to the precise forms disclosed. Many modifications and variations are possible in view of the above teachings. The implementations were chosen and described in order to best explain principles of operation and practical applications, to thereby enable others skilled in the art.

Although various drawings illustrate a number of logical stages in a particular order, stages that are not order dependent may be reordered and other stages may be combined or broken out. While some reordering or other groupings are specifically mentioned, others will be obvious to those of ordinary skill in the art, so the ordering and groupings presented herein are not an exhaustive list of alternatives. Moreover, it should be recognized that the stages can be implemented in hardware, firmware, software or any combination thereof.

What is claimed is:

1. An electronic system, comprising:
an array of voltage regulator cells, wherein the array of voltage regulator cells is configured to provide a plurality of voltage regulator sets, and each voltage regulator set is configured to output a respective rail voltage and provide the respective rail voltage to a respective power rail of a plurality of power rails; and
a plurality of reference circuits coupled to the array of voltage regulator cells, wherein each of the plurality of reference circuits is shared by, and configured to provide a respective reference voltage to, one or more respective voltage regulator cells of a respective voltage regulator set, and the respective voltage regulator set is configured to generate the respective rail voltage based on the respective reference voltage.

2. The electronic system for claim 1, further comprising a substrate, wherein the array of voltage regulator cells and the plurality of reference circuits are disposed on the substrate, separately from one another.

3. The electronic system of claim 1, wherein the plurality of power rails include a first number of power rails, and the plurality of reference circuits include a second number of reference circuits, the second number equal to or less than the first number.

4. The electronic system of claim 1, wherein each of the plurality of power rails is uniquely associated with a distinct one of the plurality of reference circuits, which is configured to provide the respective reference voltage to each voltage regulator cell in the respective voltage regulator set.

5. The electronic system of claim 1, wherein:
the plurality of power rails include a first number of power rails;
the plurality of reference circuits include a second number of reference circuits;
the array of voltage regulator cells includes a third number of voltage regulator cells;
the second number is equal to or less than (≤) the third number; and
the first number is equal to or less than (≤) the third number.

6. The electronic system of claim 1, wherein the plurality of voltage regulator sets include a first voltage regulator set that is configured to output a first rail voltage to a first power rail, and the first rail voltage is equal to a first reference voltage provided by a first reference circuit.

7. The electronic system of claim 6, further comprising a voltage controller coupled to the plurality of reference circuits, wherein the voltage controller is configured to generate a digital control signal based on the first rail voltage associated with the first power rail and provide the digital control signal to the first reference circuit defining the first reference voltage.

8. The electronic system of claim 6, wherein:
the first voltage regulator set further includes a target number of voltage regulator cells and is configured to deliver up to a predefined regulator current to the first power rail; and
the target number is determined based on the predefined regulator current.

9. The electronic system of claim 8, further comprising a voltage controller coupled to the array of voltage regulator cells;
wherein the voltage controller is configured to determine the target number based on the predefined regulator current associated with the first power rail, generate one or more select signals based on the target number, and provide the one or more select signals to the array of voltage regulator cells to select the target number of voltage regulator cells of the first voltage regulator.

10. The electronic system of claim 1, wherein voltage regulator cells in the array of voltage regulator cells are identical to each other.

11. The electronic system of claim 1, wherein at least two voltage regulator cells in the array of voltage regulator cells are different from one another.

12. The electronic system of claim 1, wherein the plurality of reference circuits are identical to one another.

13. The electronic system of claim 1, wherein a first voltage regulator cell further comprises:
a first signal generator configured to receive a target reference voltage and a first rail voltage and generate a periodic signal having a target pulse width; and
a first power stage coupled to the first signal generator and configured to generate the first rail voltage based on the periodic signal having the target pulse width; and
a first feedback path coupling an output of the first power stage to a signal input of the first signal generator.

14. The electronic system of claim 13, wherein the first voltage regulator cell further comprises:
a second feedback path coupling the output of the first power stage to a signal modulator of the first signal generator, the second feedback path configured to pull the first rail voltage back to the target reference voltage when the first rail voltage deviates from the target reference voltage at a deviation rate higher than a characteristic circuit rate of the first voltage regulator cell.

15. The electronic system of claim 14, wherein the second feedback path further comprises:
a change detector coupled to the output of the first power stage, the change detector configured to detect the first rail voltage deviating from the target reference voltage at the deviation rate; and
an amplification and modulation circuit coupled to the change detector and the signal modulator, the amplification and modulation circuit configured to adjust a pulse width of the periodic signal in real-time, when the first rail voltage deviates from the target reference voltage at the deviation rate.

16. The electronic system of claim 1, wherein each voltage regulator cell further comprises:
an error amplifier configured to receive the respective reference voltage and the respective rail voltage and generate an amplified difference signal;
a pulse width modulator coupled to the error amplifier and configured to generate a periodic signal having a pulse width and a feature frequency;
a power stage coupled to the pulse width modulator and configured to generate the respective rail voltage based on the periodic signal; and
a feedback path coupling an output of the power stage to an input of the error amplifier.

17. The electronic system of claim 1, wherein a first voltage regulator cell further comprises:
an input reference interface for receiving a target reference voltage;
an input signal interface for receiving an input signal;
an output interface for providing a first rail voltage to a first rail;
a first feedback path coupling the output interface of the first voltage regulator cell to the input signal interface of the first voltage regulator cell; and
an inductor electrically coupled between the input signal interface and the output interface.

18. The electronic system of claim 17, wherein the inductor includes one of an integrated inductor formed on a substrate of an integrated circuit including a subset of the array of voltage regulator cells or a hybrid inductor assembled onto the substrate.

19. An apparatus, comprising:
a plurality of power rails configured to providing one or more rail voltages;
an array of voltage regulator cells coupled to the plurality of power rails, wherein the array of voltage regulator cells is configured to provide a plurality of voltage regulator sets, and each voltage regulator set is configured to output a respective rail voltage to a respective power rail; and
a plurality of reference circuits coupled to the array of voltage regulator cells, wherein each of the plurality of reference circuits is shared by, and configured to provide a respective reference voltage to, one or more respective voltage regulator cells of a respective voltage regulator set, and the respective voltage regulator set is configured to generate the respective rail voltage based on the respective reference voltage.

20. A method, comprising:
grouping voltage regulator cells in an array of voltage regulator cells to provide a plurality of voltage regulator sets; and
for each of the plurality of voltage regulator sets:
generating a respective reference voltage by a respective one of a plurality of reference circuits, wherein the respective one of the plurality of reference circuits is shared by one or more respective voltage regulator cells of the respective voltage regulator set;
generating a respective rail voltage by the respective voltage regulator set based on the respective reference voltage; and
providing the respective rail voltage to drive a respective one of a plurality of power rails.
